(19) United States
(12) Patent Application Publication
(10) Pub. No.: US 2007/0199677 A1
(43) Pub. Date: Aug. 30, 2007

(54) Heat Sink Fin Structure and Manufacturing Method Thereof

(76) Inventors: Ming-Hang Hwang, Taipei City (TW); Yu-Chiang Cheng, Taipei City (TW); Chao-Yi Chen, Taipei City (TW); Ping-Feng Lee, Taipei County (TW); Hsin-Lung Kuo, Taipei City (TW); Bin-Wei Lee, Taipei City (TW); Wei-Chung Hsiao, Taipei City (TW)

Correspondence Address: LAW OFFICES OF LAI AND ASSOCIATES, P.C., 5800 RANCHESTER STE 200, HOUSTON, TX, 77036, US

(21) Appl. No.: 11/307,834

(22) Filed: Feb. 24, 2006

(51) Int. Cl. H05K 7/20

(52) U.S. Cl. 165/80.3; 165/133; 361/704

(57) ABSTRACT

This invention discloses a manufacturing method and the structure for a heat sink fin. This heat sink fin structure includes an attachment and a plurality of heat sink fins. The plurality of heat sink fins is often used in conducting the waste heat from a chip. The plurality of heat sink fins and the attachment can be made of a special thermal conduction material, including the metal and a bracket structure of carbon element which have high thermal conductivity, so as to improve the efficiency of heat conduction. The corresponding manufacturing method for this thermal conduction material can be made with chemical vapor deposition, physical vapor deposition, electroplating or the other materials preparation method. The bracket structure of carbon element can be coated on a metal surface and can be mixed into the metal.

### FIELD OF THE INVENTION

The present invention relates to a heat sink fin structure and corresponding manufacturing method and, more particularly, to a manufacturing method of making a heat conduction material having a metal and a bracket structure of carbon element.

### BACKGROUND OF THE INVENTION

In recent years, the pace of high technology industry development is extremely fast, the development of electronic components is toward small volumes and high densities. The performance requirements for the aforesaid components also increase that generates much waste heat. The efficiency of the electronic components will be decreased if the waste heat is unable to eliminate appropriately. Therefore, various heat conduction materials are provided to improve the efficiency of heat dissipation.

In the prior art, the material applying in the heat dissipation structure usually includes aluminum to be the tendency of current heat dissipation technology. Traditionally, aluminum applying in the heat dissipation material is restricted due to high temperature conduction produced by the fast development of chips that causes a bottleneck. Copper applying in the heat dissipation technology is then provided. However, copper has a higher specific gravity that has disadvantage to shape and the application is restricted. Although both copper and aluminum are used for air cooling to implement heat dissipation, the air cooling incorporating the aforesaid copper and aluminum will be unable to satisfy the demand for heat dissipating when the heat release of chips achieves 50 W/cm². Therefore, the high efficiency of heat dissipation materials is needed. A conventional heat dissipation structure for electronic components is described as follows.

Referring to FIG. 1, a schematic diagram illustrates a conventional heat dissipation structure for an electronic component. A plurality of heat sink fins 11 can be made by copper or aluminum and has a bottom plane 111 that is bound to a heat contact layer 12. The heat contact layer 12 is made by aluminum and is bound to an upper plane 141 of a chip 14. The waste heat caused by high temperature, which is generated from the operation of the chip 14, is conducted to the plurality of heat sink fins 11 via the heat contact layer 12. An air stream produce device 13 is set on a plurality of top edges 112 of the plurality of heat sink fins 11. The plurality of top edges 112 is composed of each top edge which corresponds to each hemline of each fin of the plurality of heat sink fins 11. The air stream produce device 13 is a fan. An air stream produced by the rotating of the air stream produce device 13 is brought to the plurality of heat sink fins 11, so as to discharge the waste heat. Moreover, the temperature of the electronic component can also be decreased.

Besides, diamonds are well known and have characteristics with the highest hardness, the fastest heat conduction, and the widest refraction range in current materials. Diamonds, therefore, are always one of more important materials in engineering due to the excellent characteristics. The thermal conductivity of diamonds at the normal atmospheric temperature is five times more than copper. Moreover, the thermal expansion factor of diamonds at high temperature is very small that shows the excellent efficiency for heat dissipating. The feature may help people to differentiate the adulteration of diamonds. In the prior art, many technologies and manufacture procedures have been developed to make diamonds. The direct decomposition for hydrocarbons is the most familiar method like Microwave Plasma Enhance Chemical Vapor Deposition (MPCVD) and Hot Filament CVD (HFCVD). By the aforesaid methods, polycrystalline diamond films can be deposited. The characteristic of the polycrystalline diamond films is same as the single crystal diamonds.

### SUMMARY OF THE INVENTION

Briefly, to eliminate the waste heat generated by electronic components efficiently and to face the development tendency of electronic components with small volumes and high densities, the object of the present invention is to provide a heat conduction material which is applied for a chip to dissipate the waste heat, so as to improve the efficiency of heat dissipation. Moreover, the heat conduction material provided by the present invention is not only restricted to apply for the chip, but is also applied for other heat conduction appliances.

In accordance with the present invention a heat conduction material is applied to a heat sink fin that combines a metal with a bracket structure of carbon element. The metal is copper or aluminum or other metals with high thermal conductivity and the bracket structure of carbon element is diamonds. The bracket structure of carbon element can be coated on a surface of the metal or can be mixed into the metal. The heat conduction material can be made by chemical vapor deposition (CVD), physical vapor deposition (PVD), melting or other material preparations.

Other features and advantages of the present invention and variations thereof will become apparent from the following description, drawings, and claims.

### BRIEF DESCRIPTION OF THE DRAWINGS

FIG. 1 is a schematic diagram illustrating a conventional heat dissipation structure for an electronic component;

FIG. 2 is a schematic diagram illustrating a heat sink fin structure according to an embodiment of the present invention;

FIG. 3 is a schematic diagram illustrating another heat sink fin structure according to an embodiment of the present invention;

FIG. 4 is a schematic diagram illustrating a die for making a heat sink fin structure according to FIG. 2;

FIG. 5 is a cross-sectional view illustrating a die for making another heat sink fin structure according to FIG. 3;

FIG. 6 is a schematic diagram illustrating microwave plasma enhanced chemical vapor deposition for manufacturing a heat dissipation structure according to an embodiment of the present invention; and

FIG. 7 is a schematic diagram illustrating ion beam sputtering for manufacturing a heat sink fin structure according to another embodiment of the present invention.

### DETAILED DESCRIPTION OF THE PREFERRED EMBODIMENTS

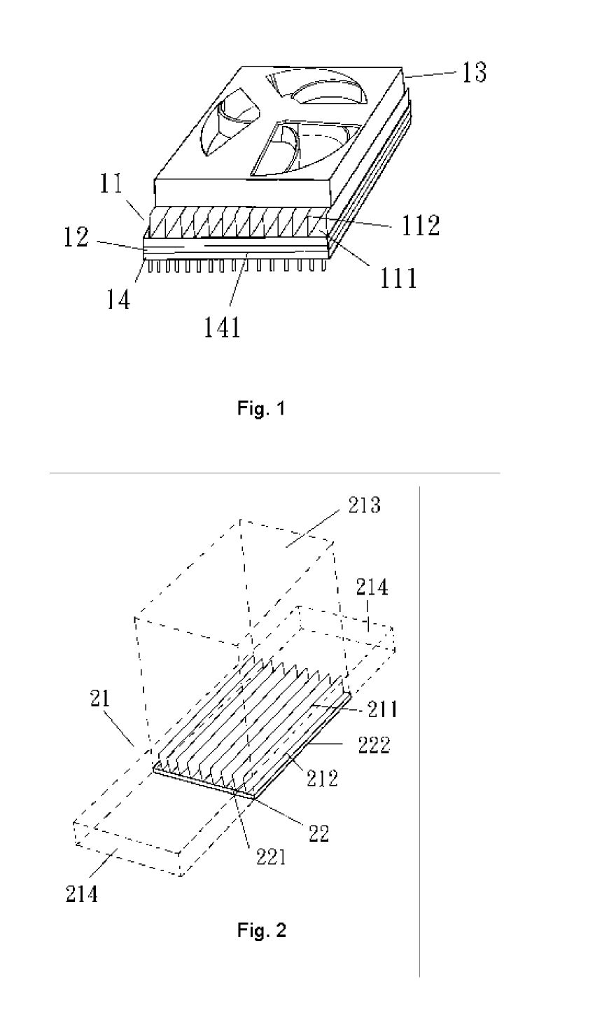

Referring to FIG. 2, a schematic illustrates a heat sink fin structure according to an embodiment of the present invention. The heat sink fin structure comprises a plurality of heat sink fins 21 and an attachment 22. The operation of the heat sink fin structure is like the prior art. A heat conduction material combining a metal with a bracket structure of carbon element is made to be the material for the plurality of heat sink fins 21 and the attachment 22. The attachment 22 has an upper surface 221 and a lower surface 222 which corresponds to the upper surface 221. A connection edge 212 is composed of a hemline of each fin of the plurality of heat sink fins 21 and is connected to a plane 221 of the attachment 22. Each fin is set to be a side by side arrangement and is vertically connected to the plane 221 of the attachment 22. Moreover, the attachment 22 has a lower plane 222 which corresponds to the plane 221 and the lower plane 222 is bound to the lower plane 141 of said chip 14 as shown in FIG. 1. The plurality of heat sink fins 21 has a plurality of top edges 211 which corresponds to the connection hemline of each fin of the plurality of heat sink fin 21. Therefore, an air inlet 213 and an air outlet 214 are composed of the plurality of heat sink fins 21, the plane 221 of the attachment 22 and the plurality of top edges 211 as shown in scopes marked by dashed lines. The air stream produce device 13 as shown in FIG. 1 can be set on the plurality of top edges 211. The heat conduction is that the lower plane 222 of the attachment 22 is bound to the upper plane 141 of the chip 14 as shown in FIG. 1. The waste heat caused by high temperature, which is generated from the operation of the chip 14, is conducted to the plurality of heat sink fins 21 and the attachment 22 for absorbing the waste heat. The plurality of heat sink fins 21 and the attachment 22 are composed of combining a metal with a bracket structure of carbon element. The bracket structure of carbon element is diamonds and the metal can be aluminum alloy or copper or other metals with high thermal conductivity or metal combinations. Air stream generated by the rotating of the air stream produce device 13 further enters the air inlet 212 to eliminate the waste heat which has been conducted to the plurality of heat sink fins 21 and lastly, the waste heat is discharged to the outside from the air outlet 213 of the plurality of heat sink fins 21.

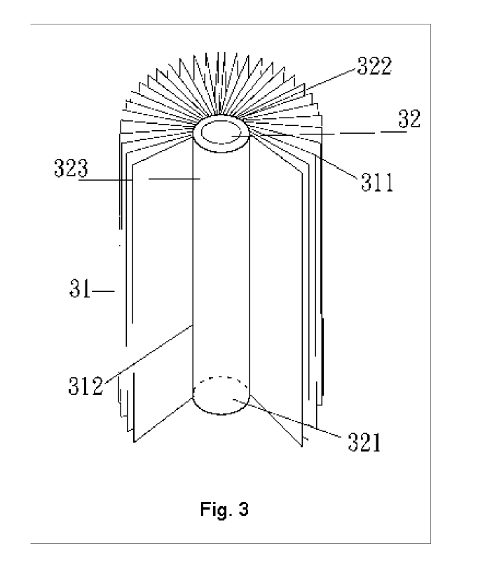

Referring to FIG. 3, a schematic diagram illustrates another heat sink fin structure according to an embodiment of the present invention. The heat sink fin structure comprises a plurality of heat sink fins 31 and an attachment 32. The heat dissipation of the heat sink fin structure is described as the prior art. A heat conduction material combining a metal with a bracket structure of carbon element is made to be a material for the plurality of heat sink fins 31 and the attachment 32. The attachment 32 is a post which is hollow without adding any stuff. A side of the host has a circular plane as a scope marked by dashed lines. The circular plane is a heat conduction end 321 and is vertically connected to an outside wall 323 of the post. The heat conduction end 321 is bound to the upper plane 141 of the chip 14 as shown in FIG. 1. A circumference 322 is formed from another side which corresponds to the heat conduction end 321 of the post. Therefore, the air stream produce device 13 as shown in FIG. 1 can be set on the circumference 322, a plurality of top edges 311. The plurality of top edges 311 is formed by each top edge of each fin of the plurality of heat sink fins 31. Each fin of the plurality of heat sink fins 31 has a connection side edge 312 for connecting the outside wall 323 of the attachment 32. A predetermined arrangement for each fin is to form a radial arrangement which is around the outside wall 323 of the attachment 32. The heat conduction is that the heat conduction end 321 of the attachment 32 is bound to the upper plane 141 of the chip as shown in FIG. 1. The waste heat caused by high temperature, which is generated from the operation of the chip 14, is conducted to the plurality of heat sink fins 31 and the attachment for absorbing the waste heat. The plurality of heat sink fins 31 and the attachment 32 are composed of combining a metal and a bracket structure of carbon element. The bracket structure of carbon element is diamonds and the metal can be aluminum alloy or copper or other metals with high thermal conductivity or metal combinations. Air stream generated by the rotating of the air stream produce device 13 further enters the plurality of heat sink fins 31 and the attachment 32 and lastly, the waste heat is discharged to the outside from the plurality of heat sink fins 31.

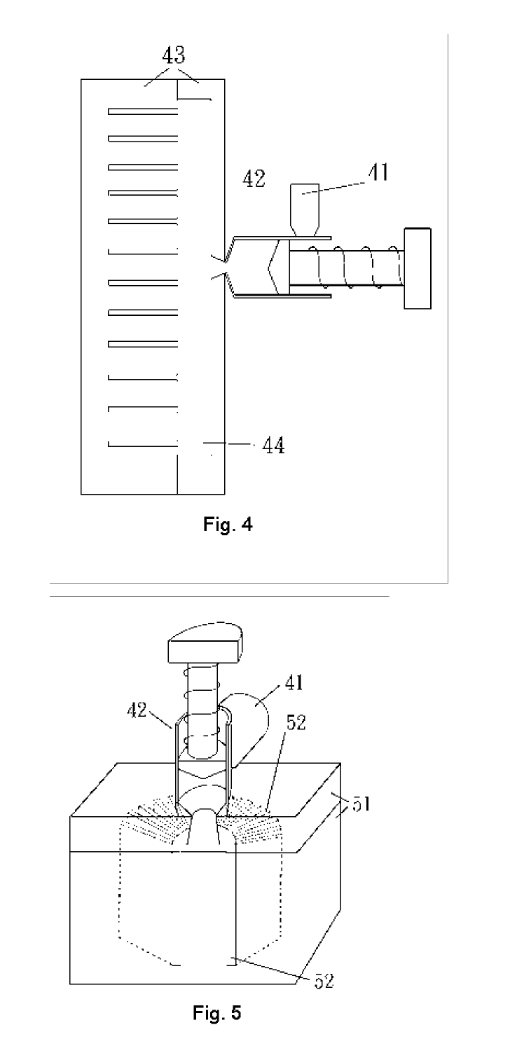

Referring to FIG. 4, a schematic diagram illustrates a die for making a heat sink fin structure according to FIG. 2. The heat sink fin structure comprises the plurality of heat sink fins 21 and the attachment 22. The die comprises a mold material supplier 41, a mold material injector 42 and a mold 43. A mold material is injected by the mold material injector 42 to a cavity 44 of the mold 43 for molding. The mold material is then formed to be the heat sink fin structure as shown FIG. 2 and the heat sink fin structure comprises the plurality of heat sink fins 21 and the attachment 22. The attachment 22 has the upper plane 221 and the lower plane 22. The upper plane 221 is connected to the plurality of heat sink fins 21. The mold material can be a melt material which combines a metal with a bracket structure of carbon element. The metal is copper or aluminum or silver or other metals with high thermal conductivity or other material combinations. The melting point of the bracket structure of carbon element is higher than any metal of the mentioned above. Therefore, the bracket structure of carbon element can be mixed into those metals.

Referring to FIG. 5, a cross-sectional view illustrates a die for making another heat sink fin structure according to FIG. 3. The heat sink fin structure comprises the plurality of heat sink fin 31 and the attachment 32. A die as shown in FIG. 4 comprises a mold material supplier 41, a mold material injector 42 and a mold 51 which is used to form the plurality of heat sink fins 31 and the attachment 32. A mold material is injected by the mold material injector 42 to a cavity 52 of the mold 51 for molding. The mold material is then formed to be the heat sink fin structure as shown FIG. 3 and the heat sink fin structure comprises the plurality of heat sink fins 31 and the attachment 32. The attachment 22 is the post and the circular plane is extended from the side of the post to form the heat conduction end 321 as shown in FIG. 3. Furthermore, the plurality of heat sink fins 31 is connected to the outside wall of the attachment 32. The mold material can be a melt material which combines a metal with a bracket structure of carbon element. The metal is copper or aluminum or silver or other metals with high thermal conductivity or other material combinations. The melting point of the bracket structure of carbon element is higher than any metal of the mentioned above. Therefore, the bracket structure of carbon element can be mixed into those metals to form the mold material.

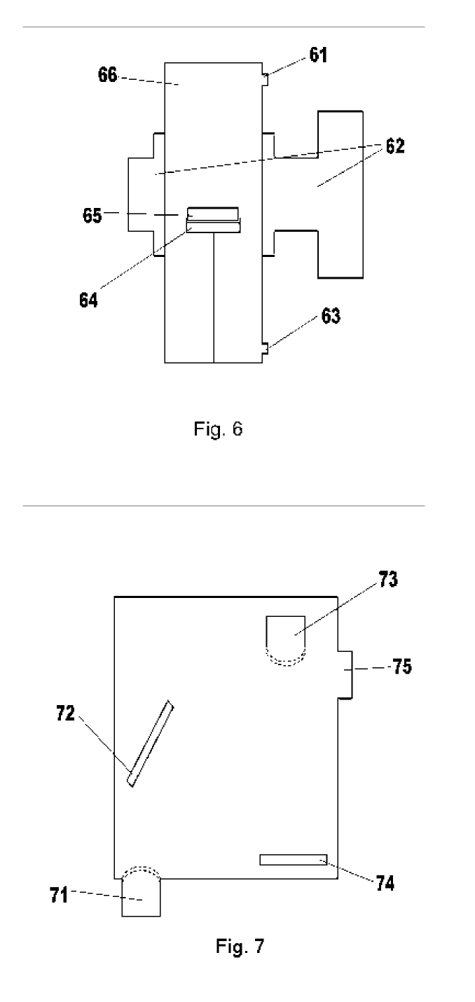

In addition, the heat conduction material having the bracket structure of carbon element can be formed on a metal surface by using CVD or PVD. Referring to FIG. 6, a schematic diagram illustrates microwave plasma enhanced chemical vapor deposition for manufacturing a heat dissipation structure according to an embodiment of the present invention. In the embodiment, the reaction procedure is that a mixed gas for desired reaction is delivered to a gas reaction room 66 from a gas entrance 61. At the same time, a microwave is generated by a microwave generation system 62 to activate the mixed gas in order to provide reactive ions for reacting. A surface of a metal material 65 on a carrier 64 is absorbed to form diamond films. The metal material 65 can be copper or aluminum or silver or other metals with high thermal conductivity or other metal combinations. Remaining gas is discharged via a waste gas exit 63. By the way mentioned above, a heat conduction material coating diamond particles can be acquired and is the heat sink fin structure as shown in FIG. 2 and FIG. 3.

Referring to FIG. 7, a schematic diagram illustrates ion beam sputtering for manufacturing a heat sink fin structure according to another embodiment of the present invention. In the embodiment, the manufacturing procedure is that a target 72 is molded by diamond materials first of all. The placement angle of the target 72 and the shooting direction of ion beam of a first ion gun 71 are approximately forty five degrees. The diamond particles fired by the first ion gun 71 fly to the front of a second ion gun 73. The diamond particles is then sputtered to the surface of a metal material 74 to form uniform diamond films by providing enough kinetic energy from the first ion gun 71. The remaining diamond particles are discharged by a waste gas exit 75. By the way mentioned above, a heat conduction material coating diamond particles can be acquired and is the heat sink fin structure as shown in FIG. 2 and FIG. 3.

Moreover, the heat conduction material having a metal and a bracket structure of carbon element can be further made by electroplating, melting except CVD and PVD of the above embodiments.

Although the features and advantages of the embodiments according to the preferred invention are disclosed, it is not limited to the embodiments described above, but encompasses any and all modifications and changes within the spirit and scope of the following claims.

What is claimed is:

1. A heat sink fin structure, comprising:
an attachment; and
a plurality of fins having at least one connection edge respectively, said at least one connection edge being connected to said attachment based on a predetermined arrangement, wherein said at least one fin is combined a metal with a bracket structure of carbon element to form a heat conduction material.

2. The heat sink fin structure of claim 1, wherein said attachment is a plane that enables said at least one connection edge of said plurality of fins to form on said plane.

3. The heat sink fin structure of claim 2, wherein said at least one connection edge is a connection hemline of said plurality of fins.

4. The heat sink fin structure of claim 3, wherein said predetermined arrangement is a vertical side by side arrangement.

5. The heat sink fin structure of claim 1, wherein said metal is copper.

6. The heat sink fin structure of claim 1, wherein said metal is aluminum.

7. The heat sink fin structure of claim 1, wherein said metal is a metal material with high thermal conductivity.

8. The heat sink fin structure of claim 1, wherein said bracket structure of carbon element is diamonds.

9. The heat sink fin structure of claim 1, wherein said attachment is a post that enables said at least one connection edge of said plurality of fin to from on an outside wall of said post.

10. The heat sink fin structure of claim 9, wherein said at least one connection edge is a connection side edge of said plurality of fins.

11. The heat sink fin structure of claim 10, whereon said predetermined arrangement is a radial arrangement to connect said outside wall of said attachment.

12. A manufacturing method for making a heat sink fin structure, applied in conducting a heat generated by a chip, said method comprising:
employing a process to form a heat conduction material having a metal and a bracket structure of carbon element;
employing a die to form an attachment; and
setting a plurality of fins having at least one connection edge, said at least one connection edge being connected to said attachment based on a predetermined arrangement.

13. The manufacturing method for making a heat sink fin structure of claim 12, wherein said metal is copper.

14. The manufacturing method for making a heat sink fin structure of claim 12, wherein said metal is aluminum.

15. The manufacturing method for making a heat sink fin structure of claim 12, wherein said metal is a metal material with high thermal conductivity.

16. The manufacturing method for making a heat sink fin structure of claim 12, wherein said bracket structure of carbon element is diamonds.

17. The manufacturing method for making a heat sink fin structure of claim 12, wherein said heat conduction material is made by chemical vapor deposition (CVD).

18. The manufacturing method for making a heat sink fin structure of claim 12, wherein said heat conduction material is made by physical vapor deposition (PVD).

19. The manufacturing method for making a heat sink fin structure of claim 12, wherein said heat conduction material is made by electroplating.

20. The manufacturing method for making a heat sink fin structure of claim 12, wherein said heat conduction material is made by melting.
